(19) United States
(12) Patent Application Publication
(10) Pub. No.: US 2026/0096399 A1
(43) Pub. Date: Apr. 2, 2026

(54) SEMICONDUCTOR DEVICE

(71) Applicant: SAMSUN ELGECTRONICS CO.,LTD., Suwon-si (KR)

(72) Inventors: Woojin JIN, Suwon-si (KR); Yunseok NOH, Suwon-si (KR); Sangun PARK, Suwon-si (KR); Taeyang YOU, Suwon-si (KR); Haemin YOO, Suwon-si (KR); Joohwan LEE, Suwon-si (KR)

(73) Assignee: SAMSUN ELGECTRONICS CO.,LTD., Suwon-si (KR)

(21) Appl. No.: 19/097,188

(22) Filed: Apr. 1, 2025

(30) Foreign Application Priority Data
Oct. 2, 2024 (KR) 10-2024-0134179
Nov. 27, 2024 (KR) 10-2024-0172252

(51) Int. Cl. H01L 21/66; H01L 23/528; H10D 89/10

(52) U.S. Cl. CPC H10P 74/273; H10D 89/10; H10W 20/43

(57) ABSTRACT

A semiconductor device includes: a first standard cell and a second standard cell at different positions in at least one of a first direction and a second direction parallel to an upper surface of a semiconductor substrate, the first standard cell and the second standard cell intersecting each other; a signal interconnection connecting the first standard cell and the second standard cell; and a monitoring interconnection connected to the signal interconnection in a vertical direction perpendicular to the upper surface and at a first level higher than a second level of the signal interconnection in the vertical direction, wherein the monitoring interconnection includes a monitoring pad in an uppermost interconnection layer at an uppermost level in the vertical direction.

### CROSS-REFERENCE TO RELATED APPLICATION

This application claims benefit of priority to Korean Patent Application Nos. 10-2024-0172252, filed on Nov. 27, 2024, and 10-2024-0134179, filed on Oct. 2, 2024, in the Korean Intellectual Property Office, the disclosures of which are incorporated herein by reference in their entireties.

### BACKGROUND

A semiconductor device may include a plurality of semiconductor elements formed on a semiconductor substrate, and a plurality of interconnections connected to at least a portion of the plurality of semiconductor elements. Generally, the plurality of interconnections may be disposed on one surface of the semiconductor substrate, and may include a plurality of power interconnections providing a transfer path for a power voltage, and a plurality of signal interconnections connected to the plurality of semiconductor elements and providing a transfer path for a signal.

In order to design a transfer path of a signal efficiently, a plurality of signal interconnections may be formed as the shortest path. To perform fault isolation after a wafer (including a semiconductor device) is fab-out, at least one of the plurality of signal interconnections may need to extend to an uppermost interconnection layer.

### SUMMARY

Provided is a semiconductor device which may facilitate fault isolation after a wafer is fab-out by connecting a monitoring interconnection (extending to an uppermost interconnection layer) to at least one of a plurality of signal interconnections that provide a transfer path for a signal in a semiconductor substrate.

According to an aspect of the disclosure, a semiconductor device includes: a semiconductor substrate; a plurality of standard cells arranged in a first direction and a second direction parallel to an upper surface of the semiconductor substrate; and a plurality of interconnections in a plurality of interconnection layers on the upper surface of the semiconductor substrate, the plurality of interconnections being connected to at least a portion of the plurality of standard cells, wherein the plurality of standard cells include a first standard cell including: a first input pin configured to receive a first input signal, and a first output pin configured to output a first output signal, wherein the plurality of interconnections include: a first signal interconnection connected to at least one of the first input pin and the first output pin, and a first monitoring interconnection electrically connected to the first signal interconnection, wherein the first signal interconnection is disposed in a first group of interconnection layers among the plurality of interconnection layers, wherein the first monitoring interconnection is disposed in a second group of interconnection layers, the second group of interconnection layers being different from the first group of interconnection layers among the plurality of interconnection layers, and wherein the second group of interconnection layers include an uppermost interconnection layer among the plurality of interconnection layers.

According to an aspect of the disclosure, a semiconductor device includes: a plurality of standard cells in a first direction and a second direction parallel to an upper surface of a semiconductor substrate, the plurality of standard cells intersecting with each other; and a plurality of interconnections in a plurality of interconnection layers on the upper surface, the plurality of interconnections being connected to at least a portion of the plurality of standard cells, wherein the plurality of standard cells include a first standard cell including a first input pin configured to receive a first input signal and a first output pin configured to output a first output signal, wherein the first standard cell includes a monitoring interconnection connected to the first input pin or the first output pin in a vertical direction perpendicular to the upper surface, the first standard cell extending to an uppermost interconnection layer among the plurality of interconnection layers, wherein the monitoring interconnection includes: a monitoring pad positioned in the uppermost interconnection layer and exposed externally, and an intermediate monitoring interconnection in an intermediate interconnection layer at a first level lower than a second level of the uppermost interconnection layer, and wherein the intermediate monitoring interconnection has an area in the intermediate interconnection layer.

According to an aspect of the disclosure, a semiconductor device includes: a first standard cell and a second standard cell at different positions in at least one of a first direction and a second direction parallel to an upper surface of a semiconductor substrate, the first standard cell and the second standard cell intersecting each other; a signal interconnection connecting the first standard cell and the second standard cell; and a monitoring interconnection connected to the signal interconnection in a vertical direction perpendicular to the upper surface and at a first level higher than a second level of the signal interconnection in the vertical direction, wherein the monitoring interconnection includes a monitoring pad in an uppermost interconnection layer at an uppermost level in the vertical direction.

### BRIEF DESCRIPTION OF DRAWINGS

The above and other aspects, features, and advantages of the disclosure will be more clearly understood from the following detailed description, taken in combination with the accompanying drawings, in which:

FIG. 1 illustrates a process of manufacturing a semiconductor device according to an example embodiment of the disclosure;

FIGS. 2A and 2B illustrate a semiconductor device according to an example embodiment of the disclosure;

FIG. 3 illustrates a semiconductor device according to an example embodiment of the disclosure;

FIGS. 4A, 4B, and 5 illustrate a connection structure of standard cells included in a semiconductor device according to an example embodiment of the disclosure;

FIG. 6 illustrates a circuit included in a semiconductor device according to an example embodiment of the disclosure;

FIGS. 7 and 8 illustrate a layout of standard cells included in a semiconductor device according to an example embodiment of the disclosure;

FIGS. 9 to 11 illustrate a process of designing a semiconductor device according to an example embodiment of the disclosure;

FIGS. 12A and 12B illustrate a standard cell included in a semiconductor device and having a monitoring interconnection defined therein according to an example embodiment of the disclosure;

FIGS. 13 and 14 illustrate a semiconductor device according to an example embodiment of the disclosure; and

FIGS. 15 to 17 illustrate a process of designing a semiconductor device according to an example embodiment of the disclosure.

### DETAILED DESCRIPTION

Hereinafter, embodiments of the disclosure will be described as follows with reference to the accompanying drawings.

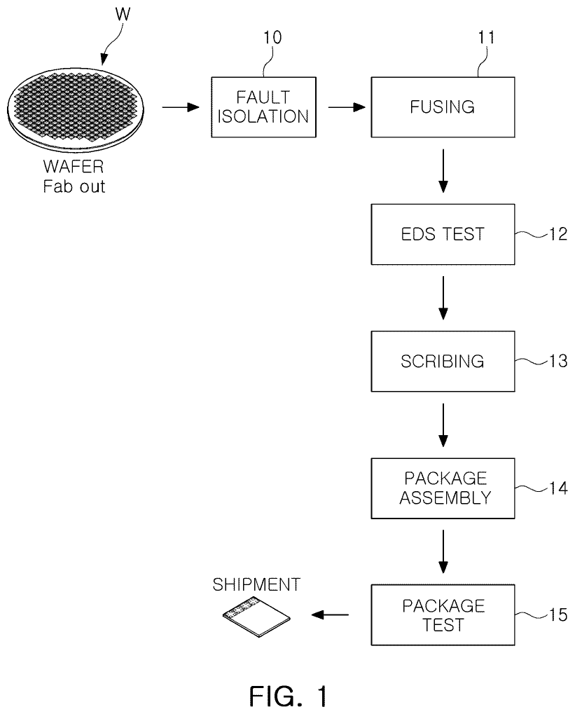

FIG. 1 illustrates a process of manufacturing a semiconductor device according to an example embodiment.

Referring to FIG. 1, a plurality of semiconductor dies may be manufactured by performing semiconductor processes on a wafer W (including the plurality of semiconductor dies) that may be fab-out. The plurality of semiconductor dies (included in the wafer W) may provide the same type of semiconductor devices. When the wafer W is fab-out, a fault isolation operation 10 may be executed on the wafer W, as illustrated in FIG. 1

Generally, the fault isolation operation 10 may be executed as an optical fault isolation operation or an electrical fault isolation operation. In the optical fault isolation operation, an optical signal may be applied to the wafer W, and in the electrical fault isolation operation, an electron beam signal may be applied to the wafer W. The optical signal and the electron beam signal may be reflected from the semiconductor device.

For example, an optical signal and/or an electron beam signal may be irradiated to a wafer such that the optical signal and/or the electron beam signal may be reflected from a target pin while the semiconductor device included in the wafer W operates. The target pin may be a pin at which a target signal to be measured for fault isolation of the semiconductor device is input or output, and may be, for example, an input pin and/or an output pin of a standard cell providing a sequential logic circuit. The fault isolation operation 10 may be performed by measuring a signal reflected from the target pin or a structure connected to the target pin.

When the fault isolation is completed, a fusing operation 11 may be executed. The fusing operation 11 may include operations such as storing data required for customizing and operating the semiconductor device in fuse cells. When the fusing operation 11 is completed, an electrical die sorting (EDS) test 12 may be performed. In an example embodiment, the EDS test 12 may include an EDS test performed multiple times under different temperature conditions. Depending on the results of the EDS test 12, the data stored in the fuse cells in the fusing operation 11 may be confirmed or may be changed.

When the EDS test 12 is completed, a scribing process 13 may be performed on the wafer W and semiconductor dies may be separated from the wafer W. Each of the semiconductor dies separated from the wafer W may be input into the package assembly process 14, the package test 15 may be performed on the package produced in the package assembly process 14, and the product may be shipped.

The process of manufacturing a plurality of semiconductor dies on a wafer W may include a process of forming a plurality of semiconductor elements on the wafer W, and a process of forming a plurality of interconnections connected to the plurality of semiconductor elements. In a design operation performed prior to manufacturing a plurality of semiconductor dies, a routing operation of disposing a plurality of standard cells stored in a standard cell library and disposing interconnections connecting the disposed standard cells may be performed. Based on the arrangement of the plurality of standard cells and the arrangement of interconnections connecting the plurality of standard cells determined in the design operation, a plurality of semiconductor elements and a plurality of interconnections may be formed.

For example, the process of forming a plurality of interconnections on a wafer W may include a process of forming a plurality of signal interconnections and a process of forming a plurality of power interconnections. In example embodiments, the plurality of signal interconnections may be formed on a first surface of the wafer W, and the plurality of power interconnections may be formed on a second surface different from the first surface of the wafer W.

In an example embodiment, in an operation of disposing a plurality of standard cells and/or a routing operation of disposing interconnections connecting the disposed standard cells, an arrangement of a monitoring interconnection to be used in the fault isolation operation 10 may be determined. The monitoring interconnection may be an interconnection extending from the plurality of interconnection layers in which a plurality of interconnections are disposed in the wafer W to the uppermost interconnection layer. For example, the monitoring interconnection may include a monitoring pad disposed in the uppermost interconnection layer, and the fault isolation operation 10 may be performed by irradiating an electron beam signal to the monitoring pad and measuring a reflective signal, or by directly probing the monitoring pad.

In an example embodiment, the monitoring interconnection may be predefined in a layout of a standard cell inputting or outputting a target signal to be measured in the fault isolation operation 10. In this case, the arrangement of the monitoring interconnection may be determined in the operation of disposing the plurality of standard cells. The monitoring interconnection may be connected to a target interconnection providing a transfer path for the target signal in at least one of the plurality of interconnection layers.

Also, in an example embodiment, the monitoring interconnection may be disposed above the target interconnection providing a transfer path for the signal to be measured in the fault isolation operation 10. In this case, the monitoring interconnection may be disposed in a post routing operation after the operation of disposing the plurality of standard cells and the routing operation of connecting the plurality of standard cells are completed. The monitoring interconnection may be disposed above the target interconnection in the direction in which the plurality of interconnection layers are stacked and may be connected to the target interconnection.

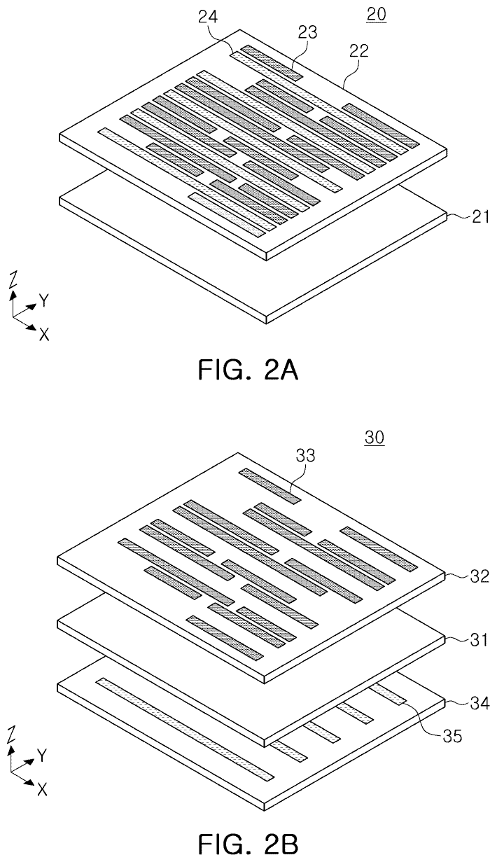

FIGS. 2A and 2B illustrate a semiconductor device according to an example embodiment.

Referring to FIG. 2A, a semiconductor device 20 according to an example embodiment may include a semiconductor substrate 21 including a semiconductor material of silicon, and an interconnection region 22 disposed on the semiconductor substrate 21. The interconnection region 22 may be disposed on an upper surface of the semiconductor substrate 21, and may include a plurality of signal interconnections 23 and a plurality of power interconnections 24 extending or disposed in the first direction (X-axis direction) and the second direction (Y-axis direction) parallel to the upper surface of the semiconductor substrate 21. The interconnection region 22 may include a plurality of interconnection layers stacked in the second direction (Z-axis direction) perpendicular to the upper surface of the semiconductor substrate 21, and the plurality of signal interconnections 23 and the plurality of power interconnections 24 may be disposed in the plurality of interconnection layers.

A plurality of semiconductor elements may be formed on the upper surface of the semiconductor substrate 21 on which the interconnection region 22 is positioned. Each of the plurality of semiconductor elements may include a gate structure disposed on an upper surface of the semiconductor substrate 21, an active region formed on an upper surface of the semiconductor substrate 21, and a contact structure connected to the gate structure and/or the active region. The contact structure may be electrically connected to the interconnection region 22.

Referring to FIG. 2B, a semiconductor device 30 according to an example embodiment may include a semiconductor substrate 31 including a semiconductor material of silicon, a first interconnection region 32 disposed on a first surface of the semiconductor substrate 31, and a second interconnection region 34 disposed on a second surface. The first surface and the second surface may be parallel to the first direction (X-axis direction) and the second direction (Y-axis direction), and may oppose each other in the third direction (Z-axis direction).

A plurality of semiconductor elements may be formed on the first surface of the semiconductor substrate 31, and a plurality of signal interconnections 33 electrically connected to the plurality of semiconductor elements may be disposed on the first interconnection region 32. Each of the plurality of signal interconnections 33 may provide a signal transfer path between at least a portion of the plurality of semiconductor elements.

The second interconnection region 34 may be provided with a plurality of power interconnections 35 supplying a power voltage required for operation of the plurality of semiconductor elements. The plurality of power interconnections 35 may be connected to the plurality of semiconductor elements formed on the first surface of the semiconductor substrate 31 through a via structure penetrating the semiconductor substrate 31.

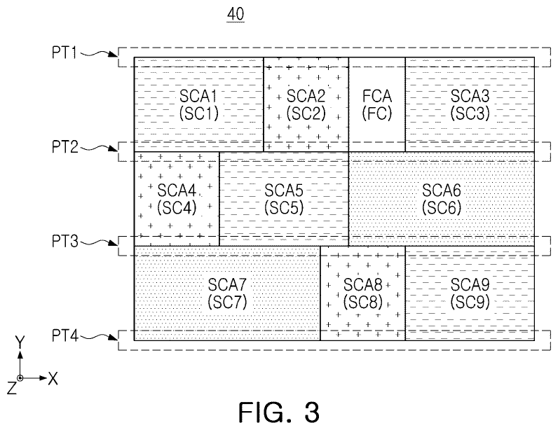

FIG. 3 illustrates a semiconductor device according to an example embodiment.

FIG. 3 may be a diagram illustrating a partial region of a semiconductor device 40. Referring to FIG. 3, the semiconductor device 40 may include a plurality of standard cell regions SCA1-SCA9 and at least one filler cell region FCA arranged in the first direction (X-axis direction) and the second direction (Y-axis direction). Each of the first direction and the second direction may be parallel to an upper surface of a semiconductor substrate included in the semiconductor device 40.

The plurality of standard cell regions SCA1-SCA9 may include a plurality of standard cells SC1-SC9, and each of the plurality of standard cells SC1-SC9 may provide an actually operating circuit. At least a portion of the plurality of standard cells SC1-SC9 may provide the same circuit. For example, each of the first, third, fifth and ninth standard cells SC1, SC3, SC5, and SC9 may provide a first circuit, each of the second, fourth, and eighth standard cells SC2, SC4, and SC8 may provide a second circuit, and each of the sixth and seventh standard cells SC6 and SC7 may provide a third circuit.

A filler cell FC may be disposed in the filler cell region FCA, and at least one semiconductor element included in the filler cell FC may not be involved in actual operations of the semiconductor device 40. The number of the plurality of standard cells SC1-SC9 and types of the plurality of standard cells SC1-SC9 may be increased and/or varied in example embodiments.

Referring to FIG. 3, a plurality of power tracks PT1-PT4 extending in the first direction and arranged in the second direction may be defined between the plurality of standard cell regions SCA1-SCA9. The plurality of standard cells SC1-SC9 may have a predetermined cell height in the second direction, and the cell height may be determined by a distance between power tracks PT1-PT4 adjacent to each other. In example embodiments, at least a portion of the plurality of standard cells SC1-SC9 may have a cell height greater than a distance between power tracks PT1-PT4 adjacent to each other.

In a structure as in an example embodiment described with reference to FIG. 2A, the plurality of power tracks PT1-PT4 may be a region allocated as an arrangement space of power interconnections 24 for transferring power voltages. However, in an example embodiment in which the signal interconnections 33 and the power interconnections 35 are disposed separately above and below the semiconductor substrate as described with reference to FIG. 2B, the power interconnections may not be disposed in the first interconnection region 32 in which the plurality of signal interconnections 33 are disposed. The plurality of power tracks PT1-PT4 may be allocated as a region in which signal interconnections electrically connected to the plurality of standard cells SC1-SC9 are disposed, thereby improving the design freedom of the signal interconnections and improving integration density of the semiconductor device 40.

At least a portion of a plurality of standard cells SC1-SC9 may be a target standard cell for inputting or outputting a target signal which may be a target of monitoring for fault isolation after a wafer including the semiconductor device 40 is fab-out. In an example embodiment, the target standard cell may include an input pin receiving an input signal from another standard cell, and/or an output pin outputting an output signal to another standard cell, and at least one of the input signal and the output signal may be selected as a target signal. For example, the target standard cell may provide a sequential logic circuit operating in synchronization with a clock signal.

In an example embodiment, a monitoring interconnection for monitoring a target signal processed by a target standard cell may be included in the semiconductor device 40. The monitoring interconnection may be electrically connected to the target interconnection transmitting the target signal. The monitoring interconnection may extend to the uppermost interconnection layer among a plurality of interconnection layers stacked in the third direction (Z-axis direction) and may include a monitoring pad disposed in the uppermost interconnection layer. When a wafer including the semiconductor device 40 is fab-out, fault isolation may be performed by measuring the target signal by irradiating an electron beam signal to the monitoring pad while the semiconductor device 40 operates and detecting the reflected signal. Alternatively, fault isolation may be performed by directly probing the monitoring pad.

In an example embodiment, the monitoring interconnection may be connected to the target interconnection connected to the target standard cell among the plurality of standard cells SC1-SC9 by a post routing operation. The post routing operation may be executed after a routing operation of disposing the plurality of standard cells SC1-SC9 and disposing signal interconnections connecting the plurality of standard cells SC1-SC9.

Also, in an example embodiment, a monitoring interconnection including a monitoring pad may be predefined for at least one target standard cell among the plurality of standard cells SC1-SC9 prior to the routing operation. For example, when the first standard cell SC1 is the target standard cell, an arrangement of monitoring interconnections extending from the target interconnection of the first standard cell SC1 to the uppermost interconnection layer may be determined preferentially before the signal interconnections connecting the first standard cell SC1 to at least one of the other standard cells SC2-SC9 are disposed. In an example embodiment, the monitoring interconnection may also be used in the routing operation of disposing signal interconnections connecting the first standard cell SC1 to at least one of the other standard cells SC2-SC9.

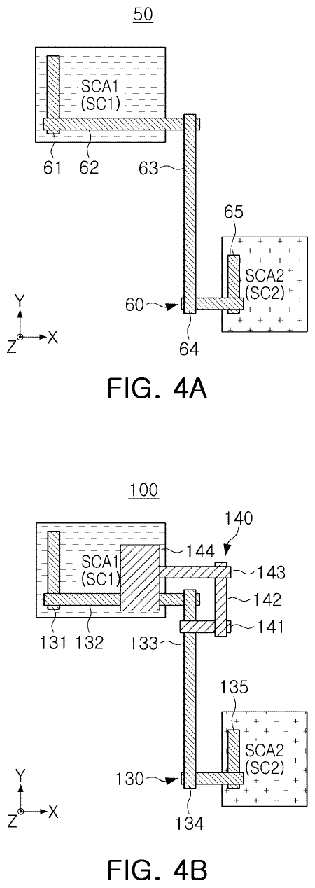

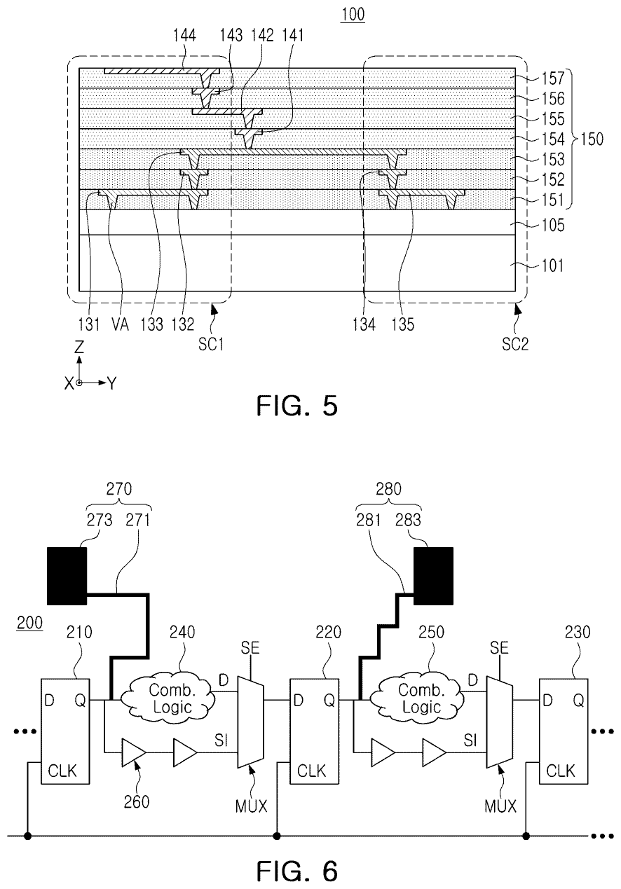

FIGS. 4A, 4B and 5 illustrate a connection structure of standard cells included in a semiconductor device according to an example embodiment.

FIGS. 4A and 4B illustrate partial regions of a semiconductor device 50 according to an example embodiment, and may be diagrams illustrating a connection structure of a first standard cell SC1 and a second standard cell SC2, for example. Referring to FIGS. 4A and 4B, the first standard cell SC1 may be disposed in the first standard cell region SCA1, the second standard cell SC2 may be disposed in the second standard cell region SCA2, and the first circuit provided by the first standard cell SC1 and the second circuit provided by the second standard cell SC2 may be different from each other.

The first standard cell SC1 and the second standard cell SC2 may be disposed at different positions in at least one of the first direction (X-axis direction) and the second direction (Y-axis direction). The first standard cell SC1 may include a first input pin receiving a first input signal, and a first output pin outputting a first output signal, and the second standard cell SC2 may include a second input pin for receiving a second input signal, and a second output pin for outputting a second output signal. For example, the first output signal may be input to the second standard cell SC2 as a second input signal.

First, referring to FIG. 4A, the first standard cell SC1 and the second standard cell SC2 may be connected to each other by a signal interconnection 60. The signal interconnection 60 may include a plurality of unit interconnections 61-65, and each of the plurality of unit interconnections 61-65 may extend in the first direction or the second direction. At least a portion of the plurality of unit interconnections 61-65 may be disposed in interconnection layers at different levels in the third direction (Z-axis direction), and also a portion of the plurality of unit interconnections 61-65 may be disposed in interconnection layers at the same level in the third direction. For example, the first unit interconnection 61 and the fifth unit interconnection 65 may be disposed in the interconnection layers at the same level in the third direction.

The signal interconnection 60 may be designed in a routing operation performed after the arrangement of the standard cells SC1 and SC2. For example, the signal interconnection 60 may be formed as the shortest route between the first standard cell SC1 and the second standard cell SC2 in consideration of transmission efficiency of the target signal transmitted between the first standard cell SC1 and the second standard cell SC2.

The signal interconnection 60 and other signal interconnections may be disposed in the plurality of interconnection layers, and in example embodiments, dummy interconnections may be further disposed in at least a portion of the plurality of interconnection layers. Accordingly, other signal interconnections and/or dummy interconnections may be disposed on the signal interconnection 60 in the third direction, and accordingly, the signal interconnection 60 may not be exposed in a state in which the wafer including the semiconductor device 50 is fab-out. In this case, the fault isolation operation of measuring the target signal transmitted through the signal interconnection 60 may not be performed.

In the example embodiment, by forming a monitoring interconnection connected to the signal interconnection providing a transfer path of the target signal and extending to the uppermost interconnection layer among the plurality of interconnection layers, the fault isolation operation of measuring the target signal may be performed through the monitoring interconnection. Referring to FIG. 4B, in the semiconductor device 100 according to an example embodiment, the first standard cell SC1 and the second standard cell SC2 may be connected to each other by the signal interconnection 130. The signal interconnection 130 may include a plurality of unit interconnections 131-135, and each of the plurality of unit interconnections 131-135 may extend in the first direction or the second direction.

As illustrated in FIG. 4B, the signal interconnection 130 may be connected to the monitoring interconnection 140. The monitoring interconnection 140 may be an interconnection extending to the uppermost interconnection layer among the plurality of interconnection layers, and may include a monitoring pad 144 disposed in the uppermost interconnection layer, and a plurality of intermediate monitoring interconnections 141-143 connecting the monitoring pad 144 to the signal interconnection 130. Each of the plurality of intermediate monitoring interconnections 141-143 may extend in the first direction or the second direction, similarly to the plurality of unit interconnections 131-135. The monitoring interconnection 140 may be connected to the uppermost unit interconnection 133, positioned at the highest level in the third direction among the plurality of unit interconnections 131-135, in the third direction. The monitoring pad 144 may be exposed in the uppermost interconnection layer.

In example embodiments, a monitoring interconnection may also be connected to the signal interconnection connecting the second standard cell SC2 to the first standard cell SC1 and a different third standard cell. The monitoring interconnection connected to the signal interconnection connecting the second standard cell to the third standard cell may have a shape different from that of the monitoring interconnection 140 illustrated in FIG. 4B and may be disposed at the same level as or at a level different from a level of the monitoring interconnection 140 in the third direction. The monitoring interconnection connected to the signal interconnection connecting the second standard cell to the third standard cell may include a monitoring pad disposed in the uppermost interconnection layer, similarly to the monitoring interconnection 140.

FIG. 5 may be a diagram illustrating a cross-sectional structure of the semiconductor device 100 illustrated in FIG. 4B. Referring to FIG. 5, the semiconductor device 100 may include a semiconductor substrate 101, an element region 105, and an interconnection region 150. The element region 105 and the interconnection region 150 may be disposed on the first surface of the semiconductor substrate 101, and a plurality of semiconductor elements may be disposed in the element region 105. For example, the element region 105 may include a plurality of semiconductor elements, contact structures and an insulating layer connected to the plurality of semiconductor elements. The plurality of semiconductor elements and the contact structures included in the element region 105 may be disposed according to the layout of each of the plurality of standard cells SC1 and SC2 arranged in the first direction and the second direction during the process of designing the semiconductor device 100.

Referring to FIG. 5, the interconnection region 150 may include a plurality of interconnection layers 151-157 stacked in the third direction (Z-axis direction). Each of the plurality of interconnection layers 151-157 may include an insulating layer, and an interconnection via VA and a unit interconnection disposed in the insulating layer, respectively.

In the example embodiment illustrated in FIG. 5, the plurality of interconnection layers 151-157 may be divided into the interconnection layers 151-153 of a first group and the interconnection layers 154-157 of a second group. For example, the interconnection layers 151-153 of the first group may include a plurality of unit interconnections 131-135 disposed in the signal interconnection 130, which provides a transfer path of a target signal between the first standard cell SC1 and the second standard cell SC2. The monitoring interconnections 140 electrically connected to the signal interconnections 130 may be disposed in the interconnection layers 154-157 of the second group may be disposed. Referring to FIG. 5, intermediate monitoring interconnections 141-143 and monitoring pad 144 may be disposed in the interconnection layers 154-157 of the second group.

The interconnection layers 151-153 of the first group and interconnection layers 154-157 of the second group may not overlap each other. In the example embodiment illustrated in FIG. 5, the interconnection layers 154-157 of the second group may be disposed above the interconnection layers 151-153 of the first group in the third direction. Accordingly, the signal interconnection 130 and the monitoring interconnection 140 may be connected to each other in the third direction. The interconnection layers 154-157 of the second group may include an uppermost interconnection layer 157 disposed at an uppermost level in the third direction, and a monitoring pad 144 may be positioned on the uppermost interconnection layer 157.

In the example embodiment illustrated in FIG. 5, the number of interconnection layers 151-153 of the first group may be smaller than the number of interconnection layers 154-157 of the second group. Accordingly, the level at which the interconnection layers 151-153 of the first group are stacked in the third direction may be smaller than the level at which the interconnection layers 154-157 of the second group are stacked in the third direction.

The size of the monitoring pad 144 may be determined depending on the method of performing the fault isolation operation after the wafer is fab-out. For example, in an example embodiment in which a fault isolation operation is performed using an electron beam signal, the monitoring pad 144 may have a first size, and in an example embodiment in which a fault isolation operation is performed by direct probing, the monitoring pad 144 may have a second size larger than the first size. In an example embodiment, the monitoring pad 144 having the first size may have a length of several tens of nanometers in each of the first and second directions.

At least one of the intermediate monitoring interconnections 141-143 included in the monitoring interconnection 140 may not overlap the first standard cell SC1 and the second standard cell SC2 in the third direction. For example, referring to FIGS. 4B and 5, the first and second unit monitoring interconnections 141 and 142 may not overlap the first standard cell SC1 and the second standard cell SC2 in the third direction. In the example embodiment illustrated in FIGS. 4B and 5, the monitoring pad 144 may be positioned in the first standard cell region SCA1 in which the first standard cell SC1 is disposed, but an example embodiment thereof is not limited thereto.

FIG. 6 illustrates a circuit included in a semiconductor device according to an example embodiment.

Referring to FIG. 6, a semiconductor device 200 according to an example embodiment may include a plurality of sequential logic circuits 210, 220, and 230, a plurality of combinational logic circuits 240 and 250, and a plurality of buffers 260. The circuit according to the example embodiment illustrated in FIG. 6 may be a scan chain circuit, and each of the plurality of sequential logic circuits 210, 220, and 230 may be a D-flip-flop.

Referring to FIG. 6, a multiplexer MUX may be connected to each input terminal of the D-flip-flop. The multiplexer MUX may select one of a data input signal D and a scan input signal SI in response to a scan enable signal SE and may input the signal to the D-flip-flop. For example, when a normal operation is executed, the data input signal D may be selected by the scan enable signal SE, and when a scan shift operation is executed, the scan input signal SI may be selected by the scan enable signal SE.

The D-flip-flop may operate in synchronization with the clock signal CLK, may latch a signal input to a rising edge of the clock signal CLK and may output the signal as an output signal Q, for example. Each of the combinational logic circuits 240 and 250 may process the output signal Q of the D-flip-flop and may generate the data input signal D of the subsequent D-flip-flop. The plurality of buffers 260 may buffer the output signal Q of the D-flip-flop and may provide the signal as a scan input signal SI to a multiplexer MUX connected to the input terminal of the subsequent D-flip-flop.

In order to perform a fault isolation operation on the semiconductor device 200 including the semiconductor device 200 after the wafer is fab-out, a signal processed by at least one of the sequential logic circuits 210, 220, and 230 may be selected as a target signal. For example, a signal output by the first sequential logic circuit 210 to the first combinational logic circuit 240 may be selected as a first target signal, and a signal output by the second sequential logic circuit 220 to the second combinational logic circuit 250 may be selected as a second target signal.

The first target signal may be transmitted by a first signal interconnection connecting a standard cell providing a D-flip-flop, which is the first sequential logic circuit 210, to another standard cell providing the first combinational logic circuit 240. Similarly, the second target signal may be transmitted by a second signal interconnection connecting a standard cell providing a D-flip-flop, which is a second sequential logic circuit 220, to another standard cell providing a second combinational logic circuit 240.

In an example embodiment, a first monitoring interconnection 270 may be connected to the first signal interconnection, and a second monitoring interconnection 280 may be connected to the second signal interconnection so as to facilitate performing a fault isolation operation after a wafer is fab-out. The first monitoring interconnection 270 may include a first intermediate monitoring interconnection 271 and a first monitoring pad 273, and the second monitoring interconnection 280 may include a second intermediate monitoring interconnection 281 and a second monitoring pad 283.

Each of the first monitoring pad 273 and the second monitoring pad 283 may be positioned on the uppermost interconnection layer of the semiconductor device 200 and may be exposed, for example, in a state in which a wafer including the semiconductor device 200 is fab-out. The first intermediate monitoring interconnection 271 may be connected between the first signal interconnection and the first monitoring pad 273, and the second intermediate monitoring interconnection 281 may be connected between the second signal interconnection and the second monitoring pad 283.

As illustrated in FIG. 6, the shape of the first intermediate monitoring interconnection 271 may be different from the shape of the second intermediate monitoring interconnection 281. In example embodiments, the number of interconnection layers in which the first intermediate monitoring interconnection 271 is disposed may also be different from the number of interconnection layers in which the second intermediate monitoring interconnection 281 is disposed. For example, when the number of interconnection layers in which the first signal interconnection is disposed is greater than the number of interconnection layers in which the second signal interconnection is disposed, the number of interconnection layers in which the first intermediate monitoring interconnection 271 is disposed may be less than the number of interconnection layers in which the second intermediate monitoring interconnection 281 is disposed.

The shape of the first monitoring pad 273 and the shape of the second monitoring pad 283 may be determined depending on the method of performing the fault isolation operation after the wafer is fab-out. For example, when the fault isolation operation is to be performed by irradiating an electron beam signal to the first monitoring pad 273 and directly probing the second monitoring pad 283, the size of the first monitoring pad 273 may be smaller than the size of the second monitoring pad 283.

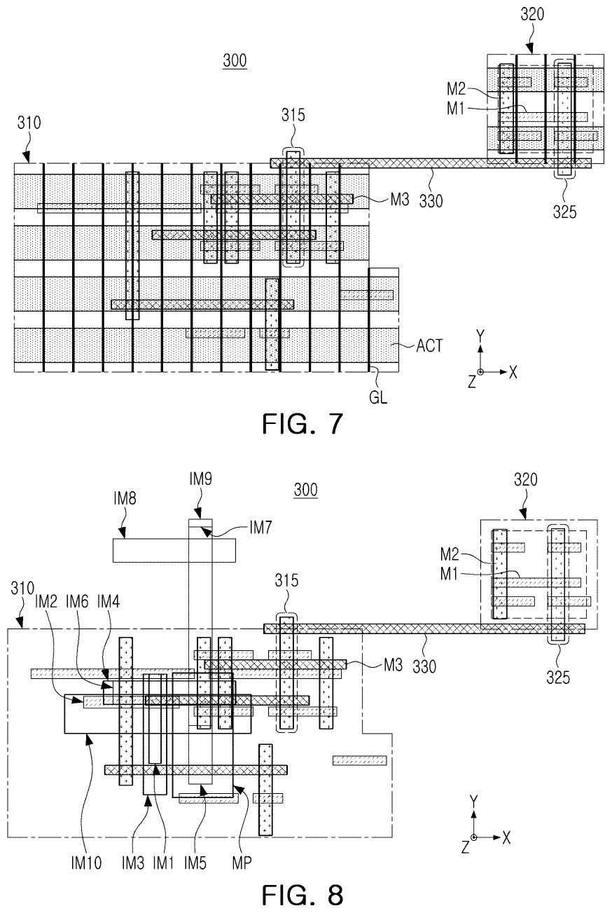

FIGS. 7 and 8 illustrate a layout of standard cells included in a semiconductor device according to an example embodiment.

FIG. 7 may be a diagram illustrating layouts of the first standard cell 310 and the second standard cell 320 among the plurality of standard cells included in a semiconductor device 300 according to an example embodiment. For example, the first standard cell 310 may provide a flip-flop, the second standard cell 320 may provide a buffer, and a scan chain circuit may be configured as described above with reference to FIG. 6. For example, an output signal output by a buffer implemented by the second standard cell 320 may be input as a scan input signal to the flip-flop implemented by the first standard cell 310.

Referring to FIG. 7, each of the first standard cell 310 and the second standard cell 320 may include a plurality of active regions ACT extending in the first direction (X-axis direction) and arranged in the second direction (Y-axis direction), and a plurality of gate structures GL extending in the second direction and arranged in the first direction. The plurality of gate structures GL and the plurality of active regions ACT may provide a plurality of elements included in each of the flip-flop implemented by the first standard cell 310 and a buffer implemented by the second standard cell 320. For example, a portion of the plurality of active regions ACT may be doped with N-type impurities, and the other portion may be doped with P-type impurities.

Referring to FIG. 7, each of the first standard cell 310 and the second standard cell 320 may include a plurality of unit interconnections M1-M3. Among the plurality of unit interconnections M1-M3, the first unit interconnection M1 may be disposed at the first level in the third direction (Z-axis direction). The second unit interconnection M2 may be disposed at the second level higher than the first level in the third direction, and the third unit interconnection M3 may be disposed at the third level higher than the second level in the third direction. The first unit interconnection M1 and the third unit interconnection M3 may extend in the first direction, and the second unit interconnection M2 may extend in the second direction.

In an example embodiment, the first unit interconnection M1 may be included in the layouts of the first standard cell 310 and the second standard cell 320 stored in the standard cell library. In other words, when the first standard cell 310 and the second standard cell 320 are selected and disposed in the operation of designing the semiconductor device 300, the position and the length of the first unit interconnection M1 may be determined based on the layout stored in the standard cell library.

In example embodiments, the second unit interconnection M2 may also be included in the layout of each of the first standard cell 310 and the second standard cell 320 stored in the standard cell library. The second unit interconnection M2 may provide an input pin 315 for receiving a scan input signal from a flip-flop implemented as the first standard cell 310, and an output pin 325 for outputting a signal from a buffer implemented as the second standard cell 320.

The third unit interconnection M3 may be disposed in a routing operation after the standard cells 310 and 320 are disposed. The third unit interconnection M3 extending in the first direction between the first standard cell 310 and the second standard cell 320 may provide a signal interconnection 330 for connecting the input pin 315 of the first standard cell 310 and the output pin 325 of the second standard cell 320 to each other.

When a wafer including a semiconductor device 300 is fab-out, a fault isolation operation of detecting a scan input signal transmitted through the signal interconnection 330 while operating the semiconductor device 300 may be executed. In order to perform the fault isolation operation, a means for irradiating an optical signal and an electron beam signal to the signal interconnection 330, or a means for directly probing the signal interconnection 330 may be necessary.

In an example embodiment, a means required for the fault isolation operation may be provided by further forming a monitoring interconnection extending in the third direction from the signal interconnection 330. Referring to FIG. 8, the monitoring interconnection may include a plurality of intermediate monitoring interconnections IM1-IM10 and a monitoring pad MP, and the monitoring pad MP may be disposed in the uppermost interconnection layer. Accordingly, after the wafer is fab-out, the fault isolation operation may be performed using a method of irradiating an electron beam signal to the monitoring pad MP and measuring the reflected signal, or using a method of directly probing the monitoring pad MP.

Each of the plurality of intermediate monitoring interconnections IM1-IM10 may extend in the first direction or the second direction, and may be positioned at different levels in the third direction. For example, the first intermediate monitoring interconnection IM1 may be positioned at the lowest level in the third direction, and the tenth intermediate monitoring interconnection IM10 may be positioned at the highest level. The first intermediate monitoring interconnection IM1 may extend in the second direction and may be electrically connected to the third signal interconnection M3 connected to the input pin 315 of the first standard cell 310.

Referring to FIG. 8, at least a portion of the plurality of intermediate monitoring interconnections IM1-IM10 may be disposed at a different position deviating from the first standard cell 310, or may extend across a boundary of the first standard cell 310. In the example embodiment illustrated in FIG. 8, the seventh and ninth intermediate monitoring interconnections IM7 and IM9 may extend in the second direction across the boundary of the first standard cell 310. Also in the example embodiment illustrated in FIG. 8, the eighth intermediate monitoring interconnection IM8 may be disposed in a position deviating from that of the first standard cell 310.

The positions and shapes of the plurality of intermediate monitoring interconnections IM1-IM10 and the monitoring pad MP may be determined in the post routing operation according to design rules. For example, at least one of the plurality of intermediate monitoring interconnections IM1-IM10 may have a minimum area able to be disposed in the interconnection layer. For example, the minimum area in the interconnection layer can be defined according to a design rule for the semiconductor device 300. Each of the plurality of intermediate monitoring interconnections IM1-IM10 may be disposed on the (minimum) area. Also, the plurality of intermediate monitoring interconnections IM1-IM10 may be disposed so as not to interfere with the signal interconnections connected to the first standard cell 310 and the second standard cell 320 and other standard cells. The position of the monitoring pad MP may also be adjusted in consideration of interference with the interconnection disposed in the uppermost interconnection layer.

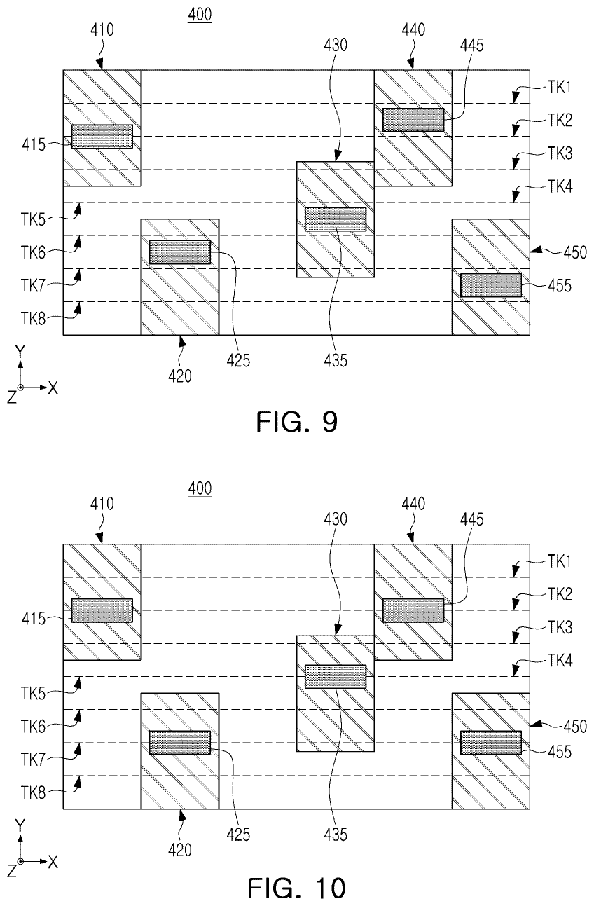

FIGS. 9 to 11 illustrate a process of designing a semiconductor device according to an example embodiment.

As described above, when a wafer including a semiconductor device 400 is fab-out, a fault isolation operation may be performed. The fault isolation operation may include an operation of detecting a target signal input and output from a target pin included in at least one target standard cell among standard cells included in the semiconductor device 400. The target signal may be isolated by irradiating an electron beam signal and an optical signal to the target pin, and measuring the reflected signal, or may be isolated by directly probing a pad electrically connected to the target pin.

Referring to FIG. 9, target standard cells 410-450 inputting and outputting the target signal may be arranged in the first direction (X-axis direction) and the second direction (Y-axis direction). A plurality of interconnection layers may be disposed above the target standard cells 410-450 in the third direction (Z-axis direction). Referring to FIG. 9, a plurality of tracks TK1-TK8 extending in the first direction and arranged in the third direction may be defined, and the plurality of tracks TK1-TK8 may be defined in the uppermost interconnection layer among the plurality of interconnection layers. For example, the uppermost interconnections disposed in the uppermost interconnection layer may have a shape extending in the first direction.

Each of the target standard cells 410-450 may include a target pin inputting and outputting a target signal, and the target pins of the target standard cells 410-450 may be electrically connected to the monitoring pads 415-455 disposed in the uppermost interconnection layer. In the example embodiment illustrated in FIG. 9, the position of each of the monitoring pads 415-455 may be determined in a post routing operation after the disposing and routing operation of disposing and connecting standard cells including the target standard cells 410-450 to each other is completed.

As illustrated in FIG. 9, initial positions of the monitoring pads 415-455 determined in the post routing operation may be different from each other. For example, the initial position of the first monitoring pad 415 connected to the first target standard cell 410 may be different from the initial position of the second monitoring pad 425 connected to the second target standard cell 420, and may be the same as the initial position of the third monitoring pad 435 connected to the third target standard cell 430.

In example embodiments, the initial position of at least one of the monitoring pads 415-455 determined by the post routing operation may not match the position of each of the plurality of tracks TK1-TK8 defined in the uppermost interconnection layer. Referring to FIG. 9, the positions of the second to fifth monitoring pads 425-455, other than the first monitoring pad 415, may not match the plurality of tracks TK1-TK8. In this case, as illustrated in FIG. 10, the positions of the monitoring pads 415-455 may be adjusted to match the positions of the plurality of tracks TK1-TK8, respectively. In the example embodiment illustrated in FIGS. 9 and 10, since the plurality of tracks TK1-TK8 extend in the first direction and are arranged in the second direction, the positions of the second to fifth monitoring pads 425-455 may be adjusted in the second direction.

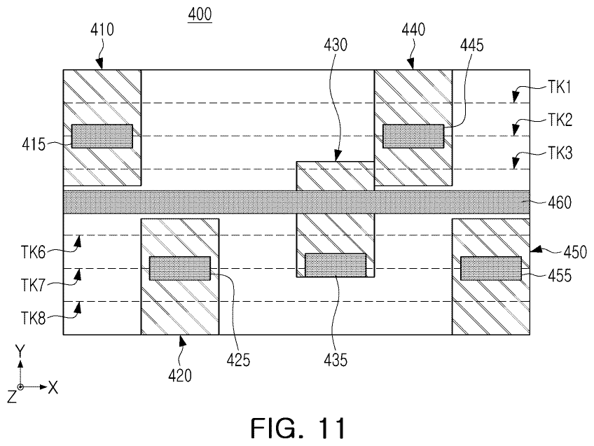

However, in example embodiments, in at least one of the tracks on which the monitoring pads 415-455 are positioned, another uppermost interconnection 460 may need to be disposed. In this case, as illustrated in FIG. 11, the position of at least one of the monitoring pads 415-455 may be adjusted so as not to interfere with the uppermost interconnection 460 to be disposed. In the example embodiment illustrated in FIG. 11, the position of the third monitoring pad 435 positioned on the fourth track TK4, in which the uppermost interconnection 460 is disposed, may be adjusted to the sixth track TK6.

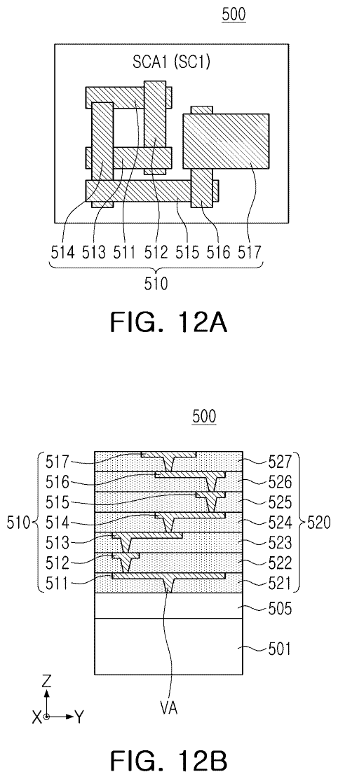

FIGS. 12A and 12B illustrate a standard cell included in a semiconductor device and having a monitoring interconnection defined therein according to an example embodiment.

As described with reference to FIG. 3 above, the semiconductor device 500 may include a plurality of standard cells arranged in the first direction (X-axis direction) and the second direction (Y-axis direction), and the plurality of standard cells may be connected to signal interconnections. At least one of the plurality of standard cells may be a target standard cell inputting or outputting a target signal to be measured in a fault isolation operation performed after a wafer is fab-out, and a monitoring interconnection may be connected to a target pin inputting or outputting the target signal from the target standard cell. The monitoring interconnection may be electrically connected to the target pin, and may extend to a monitoring pad disposed in an uppermost interconnection layer among the plurality of interconnection layers on which the signal interconnections are disposed.

In an example embodiment described with reference to FIGS. 12A and 12B, the arrangement of the monitoring interconnection may be defined preferentially before the target standard cell is disposed and a routing operation of connecting the target standard cell to another standard cell is executed. Referring to FIGS. 12A and 12B, the target standard cell may be a first standard cell SC1 disposed in a first standard cell region SCA1 of the semiconductor device 500. The first standard cell SC1 may include a plurality of semiconductor elements disposed in an element region 505 on a semiconductor substrate 501, a plurality of interconnections 511-517 disposed in a plurality of interconnection layers 521-527 included in an interconnection region 520 on the element region 505, and a plurality of vias VA.

The arrangement of the plurality of semiconductor elements included in the element region 505, and the arrangement of at least a portion of the plurality of interconnections 510 may be defined in the layout of the first standard cell SC1. For example, the first interconnection 511 disposed closest to the element region 505 may be a target pin inputting or outputting a target signal, and the position and the shape of the first interconnection 511 may be defined in the layout of the first standard cell SC1.

At least a portion of other interconnections 512-517 disposed above the first interconnection 511 in the third direction (Z-axis direction) may provide a monitoring interconnection connected to the target pin. The monitoring interconnection may extend to the uppermost interconnection layer 527 among the plurality of interconnection layers 521-527. For example, the uppermost interconnection 517 disposed in the uppermost interconnection layer 527 may provide a monitoring pad receiving an electron beam signal or directly probed by an external probe device.

The arrangement and shape of each of the other interconnections 512-517 providing monitoring interconnection may not be defined by the layout of the first standard cell SC1 stored in the standard cell library, and may be determined after the first standard cell SC1 is disposed in the first standard cell region SCA1. In example embodiments, the arrangement and shape of the interconnections 512-517 providing monitoring interconnection may be defined for the first standard cell region SCA1 and also the entirety of the first standard cells SC1 included in the semiconductor device 500, or the arrangement and shape of the interconnections 512-517 providing monitoring interconnection may be defined only for first standard cells SC1 included in the semiconductor device 500. Also, the arrangement and/or shape of the interconnections 512-517 providing a monitoring interconnection may be defined differently for the first standard cells SC1 disposed in different standard cell regions.

In an example embodiment, at least one of the monitoring interconnections may be defined to have an (minimum) area in each of the interconnection layers 522-527. Accordingly, the area occupied by other interconnections 512-517 extending from the first standard cell region SCA1 to the uppermost interconnection layer 527 providing the monitoring interconnection may be reduced, and a space in which interconnections connected to other standard cells may be disposed may be sufficiently assured.

At least one of the monitoring interconnections may be provided as a signal interconnection electrically connecting another standard cell included in the semiconductor device 500 to the target pin 511 of the first standard cell SC1. For example, the second interconnection 512 positioned in the second interconnection layer 522 may be connected to the signal interconnection connecting the target pin 511 of the first standard cell SC1 to another standard cell in the first direction and/or the second direction. In this case, the third to seventh interconnections 513-517 may be defined as the monitoring interconnection.

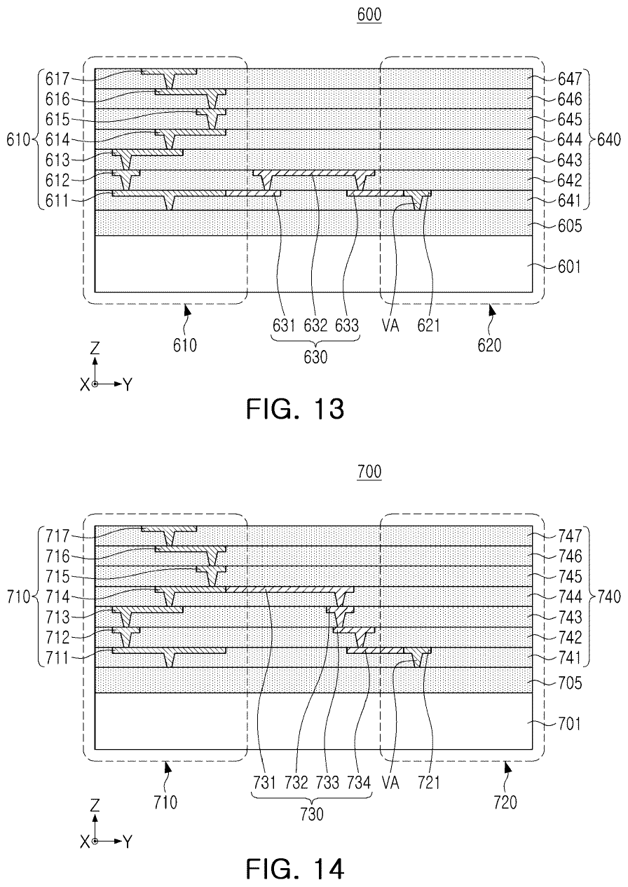

In example embodiments, the target pin 511 may be connected to the signal interconnection connecting the target pin 511 to another standard cell in the first direction and/or the second direction. In this case, the second to seventh interconnections 512-517 may provide the monitoring interconnection, which will be described in greater detail below with reference to FIGS. 13 and 14.

FIGS. 13 and 14 illustrate a semiconductor device according to an example embodiment.

Referring to FIG. 13, a semiconductor device 600 may include a first standard cell 610 and a second standard cell 620. The first standard cell 610 and the second standard cell 620 may be disposed at different positions in the first direction (X-axis direction) and/or the second direction (Y-axis direction). The first standard cell 610 may include a plurality of semiconductor elements formed in an element region 605 defined on an upper surface of a semiconductor substrate 601, and interconnections 611-617 and vias VA connected to the plurality of semiconductor elements. Similarly, the second standard cell 620 may include a plurality of semiconductor elements formed in the element region 605, and at least one interconnection 621 and at least one via VA connected to the plurality of semiconductor elements. The interconnections 611-617 (621) may be disposed in a plurality of interconnection layers 641-647 included in an interconnection region 640.

In the example embodiment illustrated in FIG. 13, among the interconnections 611-617 included in the first standard cell 610, the first interconnection 611 disposed in the first interconnection layer 641 may be a target pin inputting or outputting a target signal. The target signal may be measured in a fault isolation operation performed after a wafer including the semiconductor device 600 is fab-out, and may be, for example, an input signal and/or an output signal of a sequential logic circuit.

The second to seventh interconnections 612-617 included in the first standard cell 610 may provide a monitoring interconnection necessary for performing the fault isolation operation. For example, the seventh interconnection 617 may provide a monitoring pad and the second to sixth interconnections 612-616 may provide an intermediate monitoring interconnection. When the wafer is fab-out, a fault isolation operation may be performed by detecting a target signal by irradiating an electron beam signal to the seventh interconnection 617 provided as a monitoring pad and measuring the reflected signal, and detecting the target signal by allowing the probe device to be in direct contact with the seventh interconnection 617.

Referring to FIG. 13, the first standard cell 610 and the second standard cell 620 may be connected to each other by signal interconnections 631-633 (630). The signal interconnections 630 may be disposed in the interconnection layers 641 and 642 of the first group among the plurality of interconnection layers 640. The second to seventh interconnections 612-617 providing the monitoring interconnection may be disposed in the interconnection layers 642-647 of the second group, different from the interconnection layers 641 and 642 of the first group. In example embodiments, a length of each of the second to sixth interconnections 612-616 providing the intermediate monitoring interconnection may be shorter than a length of the signal interconnections 630. For example, a length of each of the second to sixth interconnections 612-616 and a length of the signal interconnection 630 may be defined in the first direction or in the second direction, which is a longitudinal direction in which each of the second to sixth interconnections and the signal interconnection extends relatively longer. Referring to FIG. 13, a length of the signal interconnection 630 and a length of the fourth interconnection 614 can be defined along the second direction.

One of the interconnections 611-617 included in the first standard cell 610 may be connected to one of the unit interconnections 631-633 included in the signal interconnection 630. In the example embodiment illustrated in FIG. 13, the first interconnection 611 providing the target pin may be connected to the first unit interconnection 631 disposed in the first interconnection layer 641 among the unit interconnections 631-633 included in the signal interconnection 630. For example, the first interconnection 611 and the first unit interconnection 631 may be physically connected to each other in the first direction or the second direction as illustrated in FIG. 13, and the first interconnection 611 and the first unit interconnection 631 may be provided as a single physical structure.

At least one of the second to seventh interconnections 612-617 providing the monitoring interconnection may be positioned at the same level in the third direction as at least one of the unit interconnections 631-633 included in the signal interconnection 630. Referring to FIG. 13, the second interconnection 612 included in the monitoring interconnection may be positioned at the same level in the third direction as the second unit interconnection 632 included in the signal interconnection 630.

Referring to FIG. 14, the semiconductor device 700 may include a first standard cell 710 and a second standard cell 720. As described with reference to FIG. 13, the first standard cell 710 may include a plurality of semiconductor elements formed in an element region 705 defined on an upper surface of a semiconductor substrate 701, and interconnections 711-717 and vias VA connected to the plurality of semiconductor elements. The second standard cell 720 may include a plurality of semiconductor elements formed in the element region 705, and at least one interconnection 721 and at least one via VA connected to the plurality of semiconductor elements. The interconnections 711-717 (721) may be disposed in the plurality of interconnection layers 741-747 included in an interconnection region 740

Among the interconnections 711-717 included in the first standard cell 710, the first interconnection 711 disposed in the first interconnection layer 741 may be a target pin inputting or outputting a target signal. The first interconnection 711 may be connected to the other interconnections 712-717 extending from the second interconnection layer 742 to the uppermost interconnection layer 747, and the seventh interconnection 717 may provide a monitoring pad necessary for performing a fault isolation operation.

In the example embodiment illustrated in FIG. 14, the fourth interconnection 714 among the interconnections 711-717 included in the first standard cell 710 may be connected to the signal interconnection 731-734 (730). In the example embodiment illustrated in FIG. 14, the second to fourth interconnections 712-714 among the second to seventh interconnections 712-717 disposed on the first interconnection 711 provided as the target pin may provide a target interconnection connected to the target pin in the first standard cell 710. The second to fourth interconnections 712-714 provided as the target interconnections may provide a transfer path for exchanging target signals with the second standard cell 720 together with the signal interconnection 730. The fifth to seventh interconnections 715-717 may provide a monitoring interconnection. By the fifth to seventh interconnections 715-717, the target pin may be electrically connected to the seventh interconnection 717 of the uppermost interconnection layer 747, and a fault isolation operation may be performed by measuring the target signal by applying an electron beam signal to the seventh interconnection 717 and/or directly probing the seventh interconnection 717.

According to the example embodiment illustrated in FIG. 14, signal interconnections 730 may be disposed in the interconnection layers 741-744 of a first group among the plurality of interconnection layers 740. The fifth to seventh interconnections 715-717 providing monitoring interconnection may be disposed in the interconnection layers 745-747 of a second group different from the interconnection layers 741-744 of the first group.

In example embodiments, a length of each of the fifth and the sixth interconnections 715 and 716 providing an intermediate monitoring interconnection may be shorter than a length of the signal interconnections 730. For example, a length of each of the fifth and the sixth interconnections 715 and 716 and a length of the signal interconnection 730 may be defined in the first direction or in the second direction, which is a longitudinal direction in which each of the second to sixth interconnections and the signal interconnection extends relatively longer. Referring to FIG. 14, a length of the signal interconnection 730 and a length of the sixth interconnection 716 can be defined along the second direction.

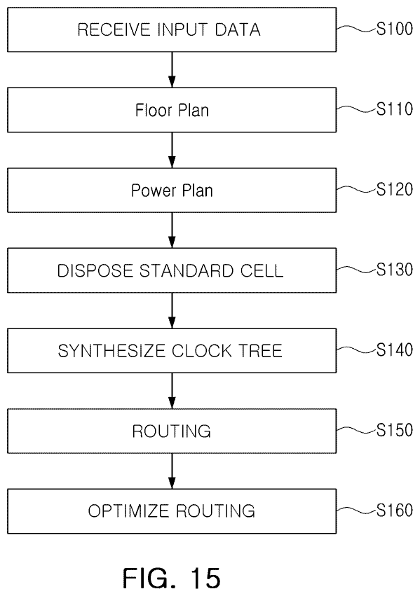

FIGS. 15 to 17 illustrate a process of designing a semiconductor device according to an example embodiment.

Referring to FIG. 15, a process of designing a semiconductor device according to an example embodiment may start with receiving input data (S100). The input data may include register transfer level (RTL) data including information about an integrated circuit. The RTL data may define a function of the semiconductor device and may include code represented in a language such as VHSIC hardware description language (VHDL), Verilog, or the like.

Thereafter, a floor plan based on the input data may be executed (S110). In the floor plan, a logically designed schematic circuit may be physically designed. The information of rough layout of logic gates included in the semiconductor device may be determined by the floor plan. In operation S110, a site-row, which is a standard cell region for disposing standard cells stored in a standard cell library according to a predefined design rule, and a routing track, which is a disposed signal interconnection for connecting standard cells to each other, may be generated.

Thereafter, a power plan may be executed (S120), and the arrangement of power interconnections supplying power voltage required for operation of the semiconductor device may be determined in the power plan. For example, signal interconnections and power interconnections may be disposed together on one surface of the semiconductor substrate, or signal interconnections may be disposed on a first surface of the semiconductor substrate and power interconnections may be disposed on a second surface opposing the first surface of the semiconductor substrate.

When the power plan is completed, at least a portion of standard cells stored in the standard cell library may be selected and disposed (S130). In an example embodiment, standard cells may be disposed according to the site-row determined in the floor plan executed in operation S110. Each of the standard cells may be disposed to correspond to the shortest interconnection path searched for by the design tool, and when the standard cells are disposed, a clock tree may be synthesized (S140), and a routing operation may be executed (S150). In the routing operation, signal interconnections connecting standard cells and power interconnections connected to at least a portion of the standard cells may be disposed.

Thereafter, routing optimization may be performed (S160). The routing optimization may include a static timing analysis operation and a timing update operation, and it may be determined whether a setup timing violation or a hold timing violation occurs in the sequential logic circuit of the flip-flop during the routing optimization. For example, when it is determined that a timing violation occurs, at least a portion of the signal interconnections generated in the routing operation of the standard cells disposed in operation S130 and operation S150 may be modified. Thereafter, a verification operation for the design rule may be executed.

When layout data is generated by the method described with reference to FIG. 15, by performing semiconductor processes such as photolithography, deposition, and etching on a wafer based on the generated layout data, a semiconductor device may be manufactured. When the semiconductor device is manufactured, the wafer may be fab-out, and a fault isolation operation may be performed on the wafer. The fault isolation operation may include an operation of measuring a target signal input or output by at least one target circuit among circuits included in the semiconductor device.

The target circuit may be provided by a target standard cell among the plurality of standard cells disposed in operation S130, and the target signal may be input to or output from a target pin defined in the target standard cell. In an example embodiment, a monitoring interconnection may be electrically connected to the target pin such that the fault isolation operation may be performed after the wafer is fab-out. The monitoring interconnection may be an interconnection extending from the target pin to an uppermost interconnection layer positioned at the highest level among the interconnection layers included in the semiconductor device. The monitoring interconnection may include a monitoring pad receiving an electron beam signal in the fault isolation operation or in direct contact with an external probe device.

In an example embodiment, the monitoring interconnection may be generated in a post routing operation performed on layout data after the routing optimization of operation S160 is completed. In an example embodiment, the monitoring interconnection may be generated in advance for a target standard cell among the disposed standard cells in operation S130, prior to the routing operation of operation S150. In this case, the arrangement of the monitoring interconnection for a target standard cell among the disposed standard cells in the operation of disposing a standard cell in operation S130 may be determined in advance, and the routing operation may be executed thereafter. For example, the monitoring interconnection may be used to connect the target standard cell to another standard cell in the routing operation.

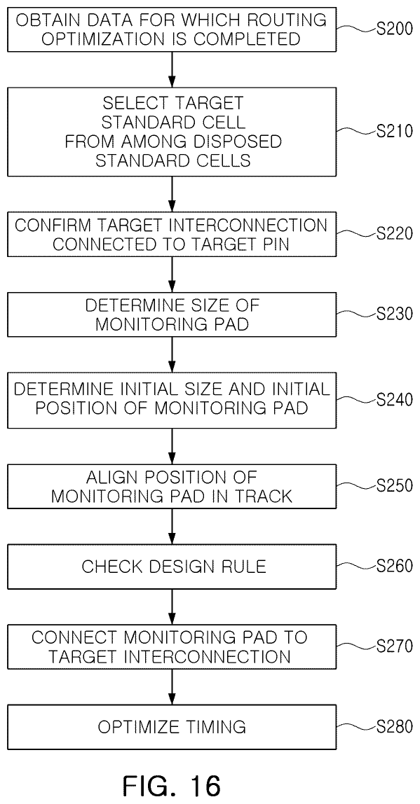

FIG. 16 may be a diagram illustrating an example embodiment of generating a monitoring interconnection in a post routing operation. Referring to FIG. 16, in order to generate a monitoring interconnection, data for which routing optimization is completed may be obtained (S200). The data for which routing optimization is completed may be layout data in which the arrangements and shapes of standard cells, signal interconnections, and power interconnections are determined. A target standard cell may be selected from among the standard cells included in the layout data obtained in operation S200 (S210).

When the target standard cell is selected, a target pin receiving a target signal or outputting a target signal from the target standard cell may be searched for, and the target interconnection connected to the target pin may be confirmed (S220). The target interconnection may be an interconnection included in the layout of the target standard cell stored in the standard cell library and connected to the target pin. When the target interconnection is confirmed, the size of the monitoring pad may be determined (S230). For example, the size of the monitoring pad may be varied depending on whether the fault isolation operation is performed by irradiating an electron beam signal to the monitoring pad or by allowing a probe device to be in direct contact with the monitoring pad.

Once the size of the monitoring pad is determined, an initial position of the monitoring pad may be determined together with an initial size of the monitoring pad (S240). For example, the initial position of the monitoring pad may be selected under the condition in which the length of the intermediate monitoring interconnections connecting the monitoring pad to the target interconnection is minimized. However, the initial position determined as above may not be aligned with the plurality of tracks defined in the uppermost interconnection layer on which the monitoring pad is positioned as described above with reference to FIG. 9. Accordingly, by adjusting the position of the monitoring pad, the pads may be aligned with one of the plurality of tracks (S250).

Thereafter, the design rule may be checked (S260). Based on the predetermined design rule, it may be checked whether there is interference between the added monitoring interconnection and the signal interconnections included in the layout data obtained in the operation S200. When it is determined that there is interference, the position of the monitoring interconnection in the corresponding region may be changed. Thereafter, a monitoring interconnection connecting the monitoring pad and the target interconnection may be generated (S270), and the timing may be optimized (S280). In the timing optimization, a setup timing violation, hold timing violation, or the like, may be verified as described above.

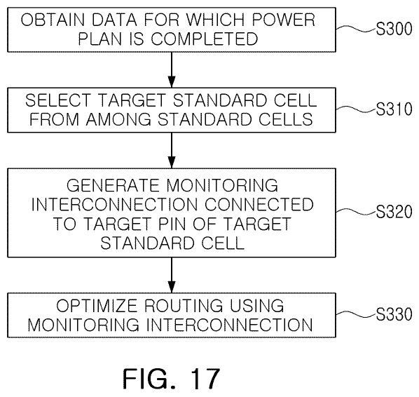

FIG. 17 may be a diagram illustrating an example embodiment in which the arrangement of monitoring interconnection is determined in advance before a routing operation. Referring to FIG. 17, in order to generate a monitoring interconnection, data for which a power plan is completed may be obtained (S300). The data for which a power plan is completed may include a site-row, which is a standard cell region in which standard cells are disposed, and a routing track in which signal interconnections connecting standard cells are disposed.

In an example embodiment described with reference to FIG. 17, before executing a routing operation of connecting standard cells, a target standard cell may be preferentially selected from among the standard cells to be disposed (S310), and a monitoring interconnection connected to a target pin of the target standard cell may be generated (S320). The target pin may correspond to a node at which the target standard cell receives a target signal or outputs a target signal as described above.

The monitoring interconnection generated in the S320 operation may extend to the uppermost interconnection layer, which is the highest level among the plurality of interconnection layers and is positioned farthest from the semiconductor substrate, and may include, for example, a monitoring pad disposed in the uppermost interconnection layer. When the monitoring interconnection is generated, in the subsequent routing operation of connecting standard cells, routing optimization may be executed using the monitoring interconnection included in the target standard cell (S330).

As an example, referring back to FIGS. 12A and 12B, before determining the arrangement of the first standard cell SC1, which is the target standard cell, the arrangement of the second to seventh interconnections 512-517 providing the monitoring interconnection may be determined. Thereafter, when the first standard cell is disposed, at least one of the second to seventh interconnections 512-517 may be used for routing in the operation of connecting the first standard cell to another standard cell.

According to the aforementioned example embodiments, after the wafer is fab-out, a monitoring interconnection extending to the uppermost interconnection layer may be connected to at least one target interconnection providing a transfer path of a target signal to be measured for fault isolation. Accordingly, by applying an electron beam signal to the monitoring interconnection, fault isolation may be easily performed after the wafer is fab-out. The monitoring interconnection may be defined in advance and disposed in one of the standard cells connected to the target interconnection, or may be formed in a post routing process performed after the target interconnection is formed. Accordingly, the monitoring interconnection reducing a decrease in efficiency of the design operation of the semiconductor device and necessary to easily perform fault isolation may be assured.

While the example embodiments have been illustrated and described above, it will be configured as apparent to those skilled in the art that modifications and variations could be made without departing from the scope of the disclosure as defined by the appended claims.

What is claimed is:

1. A semiconductor device comprising:
a semiconductor substrate;
a plurality of standard cells arranged in a first direction and a second direction parallel to an upper surface of the semiconductor substrate; and
a plurality of interconnections in a plurality of interconnection layers on the upper surface of the semiconductor substrate, the plurality of interconnections being connected to at least a portion of the plurality of standard cells,
wherein the plurality of standard cells comprise a first standard cell comprising:
a first input pin configured to receive a first input signal, and
a first output pin configured to output a first output signal,
wherein the plurality of interconnections comprise:
a first signal interconnection connected to at least one of the first input pin and the first output pin, and
a first monitoring interconnection electrically connected to the first signal interconnection,
wherein the first signal interconnection is disposed in a first group of interconnection layers among the plurality of interconnection layers,
wherein the first monitoring interconnection is disposed in a second group of interconnection layers, the second group of interconnection layers being different from the first group of interconnection layers among the plurality of interconnection layers, and
wherein the second group of interconnection layers comprise an uppermost interconnection layer among the plurality of interconnection layers.

2. The semiconductor device of claim 1, wherein a first height at which the first group of interconnection layers are stacked is smaller than a second height at which the second group of interconnection layers are stacked in a vertical direction perpendicular to the upper surface of the semiconductor substrate.

3. The semiconductor device of claim 1, wherein the first standard cell comprises a sequential logic circuit.

4. The semiconductor device of claim 1, wherein the first monitoring interconnection comprises:
a plurality of intermediate first monitoring interconnections in other interconnection layers than the uppermost interconnection layer among the second group of interconnection layers, and
a first monitoring pad in the uppermost interconnection layer.

5. The semiconductor device of claim 4, wherein at least one of the plurality of intermediate first monitoring interconnections has an area in at least one of the other interconnection layers.

6. The semiconductor device of claim 4, wherein at least a portion of the plurality of intermediate first monitoring interconnections is disposed in a region of the first standard cell.

7. The semiconductor device of claim 4, wherein at least one of the plurality of intermediate first monitoring interconnections extends in the first direction or the second direction, across a boundary of the first standard cell.

8. The semiconductor device of claim 1, wherein the first monitoring interconnection is connected, in a vertical direction perpendicular to the upper surface of the semiconductor substrate, to a unit interconnection positioned at the highest level in the vertical direction in the first signal interconnection.

9. The semiconductor device of claim 1, wherein at least a portion of the first monitoring interconnection is disposed at the same level as at least a portion of the first signal interconnection in a vertical direction perpendicular to the upper surface of the semiconductor substrate.

10. The semiconductor device of claim 1, wherein the first standard cell further comprises a target interconnection connecting at least one of the first input pin and the first output pin to the first signal interconnection,
wherein the target interconnection is connected to the first monitoring interconnection in a vertical direction perpendicular to the upper surface of the semiconductor substrate, and
wherein the target interconnection is connected to a unit interconnection positioned at the highest level in the vertical direction in the first signal interconnection in at least one of the first direction and the second direction.

11. The semiconductor device of claim 1, wherein the plurality of standard cells comprise a second standard cell comprising the same circuit as the first standard cell,
wherein the second standard cell is disposed at a first position different from a second position of the first standard cell in at least one of the first direction and the second direction,
wherein the second standard cell comprises a second input pin configured to receive a second input signal and a second output pin configured to output a second output signal, and
wherein the plurality of interconnections further comprise:
a second signal interconnection connected to the second input pin or the second output pin, and
a second monitoring interconnection being at a first level higher than a second level of the second signal interconnection in a vertical direction perpendicular to the upper surface of the semiconductor substrate, the second monitoring interconnection being connected to the second signal interconnection.

12. The semiconductor device of claim 11, wherein a first shape of the first monitoring interconnection is different from a second shape of the second monitoring interconnection.

13. The semiconductor device of claim 11, wherein the first monitoring interconnection and the second monitoring interconnection are disposed at the same level in the vertical direction.

14. The semiconductor device of claim 11, wherein the first monitoring interconnection comprises a first monitoring pad in the uppermost interconnection layer and in a first standard cell region in which the first standard cell is disposed,
wherein the second monitoring interconnection comprises a second monitoring pad in the uppermost interconnection layer and in a second standard cell region in which the second standard cell is disposed, and
wherein a first position of the first monitoring pad in the first standard cell region is different from a second position of the second monitoring pad in the second standard cell region.

15. A semiconductor device comprising:
a plurality of standard cells in a first direction and a second direction parallel to an upper surface of a semiconductor substrate, the plurality of standard cells intersecting with each other; and
a plurality of interconnections in a plurality of interconnection layers on the upper surface, the plurality of interconnections being connected to at least a portion of the plurality of standard cells,
wherein the plurality of standard cells comprise a first standard cell comprising a first input pin configured to receive a first input signal and a first output pin configured to output a first output signal,
wherein the first standard cell comprises a monitoring interconnection connected to the first input pin or the first output pin in a vertical direction perpendicular to the upper surface, and the monitoring interconnection extending to an uppermost interconnection layer among the plurality of interconnection layers,
wherein the monitoring interconnection comprises:
a monitoring pad positioned in the uppermost interconnection layer and exposed externally, and
an intermediate monitoring interconnection in an intermediate interconnection layer at a first level lower than a second level of the uppermost interconnection layer,
wherein a length of the intermediate monitoring interconnection is shorter than a length of a signal interconnection connecting the first standard cell to a second standard cell, and
wherein the second standard cell is disposed in at a different position from the first standard cell.

16. The semiconductor device of claim 15, wherein the monitoring interconnection comprises a plurality of intermediate monitoring interconnections in the intermediate interconnection layer at different levels, and
wherein a portion of the plurality of intermediate monitoring interconnections extends in the first direction and the other portion of the plurality of intermediate monitoring interconnections extends in the second direction.

17. The semiconductor device of claim 15, wherein the plurality of interconnections comprises a signal interconnection connected to at least one of the first input pin and the first output pin,
wherein the signal interconnection comprises a plurality of unit interconnections at different levels in the vertical direction, and
wherein one of the plurality of unit interconnections is connected to the first input pin or the first output pin in at least one of the first direction and the second direction.

18. The semiconductor device of claim 17, wherein at least one of the plurality of unit interconnections is positioned at the same level as at least a portion of the monitoring interconnection in the vertical direction.

19. The semiconductor device of claim 15,
wherein the signal interconnection comprises a plurality of unit interconnections at different levels in the vertical direction,
wherein the first standard cell comprises a target interconnection connected between the first input pin or the first output pin and the monitoring interconnection in the vertical direction, and
wherein one of the plurality of unit interconnections is connected to the target interconnection in at least one of the first direction and the second direction.

20. A semiconductor device comprising:
a first standard cell and a second standard cell at different positions in at least one of a first direction and a second direction parallel to an upper surface of a semiconductor substrate, the first standard cell and the second standard cell intersecting each other;
a signal interconnection connecting the first standard cell and the second standard cell; and
a monitoring interconnection connected to the signal interconnection in a vertical direction perpendicular to the upper surface and at a first level higher than a second level of the signal interconnection in the vertical direction,
wherein the monitoring interconnection comprises a monitoring pad in an uppermost interconnection layer at an uppermost level in the vertical direction.
